(19) United States
(12) Patent Application Publication
(10) Pub. No.: US 2024/0141899 A1
(43) Pub. Date: May 2, 2024

(54) AXIAL PUMP WITH SPLIT PRINTED CIRCUIT BOARD ASSEMBLY (PCA)

(71) Applicant: HEWLETT PACKARD ENTERPRISE DEVELOPMENT LP, Houston, TX (US)

(72) Inventor: John P. FRANZ, Tomball, TX (US)

(21) Appl. No.: 17/976,406

(22) Filed: Oct. 28, 2022

(51) Int. Cl. F04D 3/00; F04D 29/54; H05K 7/20

(52) U.S. Cl. CPC F04D 3/00; F04D 29/548; H05K 7/20254; H05K 7/20272

(57) ABSTRACT

An axial pump for delivering liquid coolant to cool an electronic device comprises a conduit defining a liquid flow path for the liquid coolant, an impeller in the conduit, a motor stator configured to drive rotation of the impeller about an axis of rotation parallel to the liquid flow path, and a printed circuit board assembly (PCA). The PCA comprises a first printed circuit board (PCB) portion and a second PCB portion electrically connected together by a connecting portion, with the PCA straddling the conduit such that the first PCB portion is on one lateral side of the conduit and the second PCB portion is on an opposite lateral side of the conduit and the connecting portion extending across the conduit.

### INTRODUCTION

Electronic devices, such as computers, networking devices, power supply units, etc., generate heat when in use. Cooling systems may be utilized to remove heat from components of the electronic devices to keep them within desired operating temperatures. For example, liquid cooling techniques may use flows of liquid coolant to remove heat from the systems. In liquid cooling techniques, a liquid coolant from a liquid coolant loop is disposed in thermal contact with the heat generating components of the electronic device via one or more thermal devices, such as cold plates, fluidically coupled with the liquid cooling loop. For example, in computing systems cold plates may be coupled to processors or other heat generating components of the system. The liquid coolant is caused to flow through the loop and, as the coolant passes through the thermal devices, heat from the heat generating components is absorbed by the liquid coolant, thus cooling the components. As the now-heated coolant exits the thermal devices, it carries the heat away and eventually flows through a cooling device configured to remove heat therefrom, such as a heat exchanger, radiator, chiller, or the like. After being cooled, the liquid coolant may then be returned to the one or more thermal devices to cycle through the loop once again. One or more pumps may be disposed within such a liquid cooling loop to cause the liquid coolant to flow through the loop.

### BRIEF DESCRIPTION OF THE DRAWINGS

The present disclosure can be understood from the following detailed description, either alone or together with the accompanying drawings. The drawings and related description of the figures are included to provide a further understanding of the present disclosure and are incorporated in and constitute a part of this specification. The drawings illustrate one or more nonlimiting aspects and implementations of the present teachings and together with the description explain certain principles and operation. In the drawings:

FIG. 1 is a schematic diagram illustrating a perspective view of a first pump.

FIG. 2 is a schematic diagram illustrating a front view of the first pump.

FIG. 3 is a schematic diagram illustrating a top view of the first pump.

FIG. 4 is a perspective view of a second pump.

FIG. 5 is an exploded view of the second pump.

FIG. 6 is a perspective view of two stator subassemblies of the second pump.

FIG. 7 is a perspective view of a split PCA of the second pump in a decoupled state.

FIG. 8 is a perspective view of the split PCA of the second pump in a coupled state.

FIG. 9 is a perspective sectional view of the second pump with the section taken along plane 9-9 in FIG. 4.

FIG. 10 is a schematic diagram of a system and an electronic device.

### DETAILED DESCRIPTION

In some contexts, it may be desired to utilize a relatively small pump in a liquid cooling loop. For example, in some contexts it may be desired to provide small pumps within individual computing devices or other relatively small electronic devices (e.g., in contrast to the relatively larger pumps that are often disposed external to computing systems to drive liquid coolant flows through multiple devices). Such small form factor pumps may improve efficiency and performance of the liquid cooling loop, potentially reducing power usage and noise while also delivering more coolant flow (and hence better cooling). In addition, smaller pumps disposed locally to the devices they cool may also facilitate greater modularity and scalability of the system, as the pumping capacity of the system naturally scales along with the demand for cooling since each new device added to the system brings its own pump(s) with it.

To allow for pumps to be used locally to the devices to which they pump liquid coolant for cooling, the pumps generally need to be fairly small, particularly when it is desired to dispose the pump within a relatively limited space. For example, some enterprise-grade computing systems, such as high-performance compute systems, are particularly dense and often have very little free space inside. Accordingly, pumps used therewith may need to be rather small. Some small pumps have been developed, such as the micro-axial pumps described in U.S. patent Ser. No. 11/015,608 B2, the contents of which are incorporated herein by reference in their entirety. An axial pump has an impeller (the part that moves within the liquid to drive the flow) that spins along an axis that is coaxial with a flow direction of the liquid, in contrast to centrifugal pumps which have impellers that spin along an axis transverse to the flow direction of the liquid. The micro-axial pumps described in U.S. Ser. No. 11/015,608 B2 allow for a relatively large reduction in the size of the pumps without compromising effectiveness or efficiency. However, despite these advances, micro-axial pumps may still be too large for use in certain contexts, and it is thus desired to further decrease the size of the pumps to allow for their use in even smaller spaces.

But making such micro-axial pumps even smaller poses a variety of technical challenges. One problem in particular that has been encountered is that, while the mechanical components of the pumps have become smaller over successive designs, when the controller printed circuit board assembly (PCA) that controls the operation of the pump is added thereto it can unduly increase the size of the pump to the point that the pump exceeds the needed size envelope. In some pumps, the controller PCA is provided as part of a controller device separate from the pump, with the two being coupled by wires/cables. But while this approach may allow the pump part to be smaller, the total size envelope of the system (pump+controller devices) is greatly increased due to the need to find room for the two separate parts. In addition, there are other potential problems with using a separate controller, including potential severing of the connection between the controller and the pump and difficulty cooling the controller PCA (e.g., in some systems that have no airflow to dissipate heat, even a small PCA may eventually overheat). In other systems, to avoid the issues associated with having a separate controller device, the controller-PCA of a pump is integrated into the pump itself. However, in such cases the controller PCA is often attached to a top of the housing or motor of the pump. This placement results in the thickness of the PCA contributing to an increase in the overall height of the pump. This increase in height due to the thickness of the PCA may be negligible in large pumps which are already relatively tall in comparison to a PCA. But for micro-axial pumps that already have very small height dimensions, adding the thickness of the PCA thereto can be a significant increase in the overall height of the pump. For example, some micro-axial pumps disclosed herein may have dimensions around 50 mm×50 mm×16.5 mm. If a PCA having a thickness of 6.5 mm were stacked on top of such a pump the height of the pump may increase to 23 mm, which constitutes a 39% increase in height. While various microaxial pumps and PCAs may have differing dimensions and thus the exact proportion that the PCA contributes to the overall height may vary, the general principle is that the smaller the microaxial pump is the greater the percentage of its overall height will be due to the PCA. Moreover, while a pump with such dimensions is still very small compared to existing pumps, in some contexts the height dimension of this pump may render it unsuitable for its intended use case. For example, it may be desired to fit the pumps within a PCI card space or to stack two pumps atop one another or atop a cold plate within a 1U server, but a pump having an overall height of 23 mm could not be used in these ways. A reduction of the thickness of the PCA cannot easily be achieved by an amount that would alleviate the aforementioned space issues (e.g., below about 6.5 mm as mentioned above) due to the minimum functionality needed for the PCA and also because an epoxy coating may be needed to ensure water-tightness of the PCA (since it will be deployed in a system with liquid coolant).

To solve the problems noted above, the present disclosure contemplates a micro-axial pump in which the controller PCA is disposed within the housing of the pump in a manner that does not increase the height dimension thereof, and in some examples does not increase any of the dimensions of the pump. This is accomplished, in part, by arranging the PCA in a “split” configuration straddling the conduit that defines the liquid flow path through the pump, with the PCA being transverse to the flow path (e.g., parallel to the height dimension of the pump). The split configuration of the PCA means the PCA has two printed circuit board (PCB) portions that are arranged on two opposite lateral sides of the flow path with one or more connecting portions extending across (e.g., over and/or under) the flow path to electrically couple the two PCB portions together. In some examples, the two PCB portions of the PCA are physically separate PCBs and the connecting portions comprise one or more pairs of electrical connectors to electrically connect these separate PCBs together. Because the PCA is not stacked vertically on top of the motor or housing or other components of the pump, but is instead arranged transverse to and straddling the flow path, the thickness of the PCA does not contribute to the height of the pump. This may allow for pumps that are smaller than would otherwise be possible, particularly in the height dimension which may be a particularly important dimension for some applications.

In some examples, not only does the split PCA not add to the height dimension of the pump, the PCA may be arranged in such a manner that none of the dimensions of the pump are significantly increased by the addition of the PCA thereto. This is accomplished, in part, by positioning the PCA in an open space in the pump housing between other pump components, wherein due to the configuration of the other components the provisioning of the open space therebetween does not affect the size envelope of the pump. In other words, the other components do not need to be significantly rearranged or have their relative spacings widened to accommodate the open space, but instead a space that already existed between the components and was previously either empty or underutilized may be used for the PCA. For example, in some micro-axial pumps a conduit that defines the fluid flow path comprises an impeller chamber inlet portion, an impeller chamber central portion, and a transition zone between the impeller chamber inlet portion and the impeller chamber central portion (these portions are disposed in order along the axial direction of the flow path). The areas laterally adjacent the impeller chamber inlet portion and the impeller chamber central portion are generally laterally surrounded by other components (such as support structures that form part of the housing or the stator of the pump motor, for example), and thus neither the impeller chamber inlet portion nor the impeller chamber central portion has space on its lateral sides where the split PCA could be disposed. But the transition zone between these two other portions does not have any such components positioned laterally around it (or has some components around it but ones which do not fill all of the space or which can be omitted or reduced in size without affecting the functionality of the pump), and thus there is a small open space on the lateral sides of and above and below the transition zone. The split-PCA may be disposed in this open space, straddling the flow path. The length dimension of the pump is not increased relative to what it otherwise would be in order to provide this open space in which to place the PCA, because even if the PCA were not disposed in this region the impeller chamber inlet portion would still need to be disposed the same distance from the impeller chamber central portion to ensure optimal function of the impeller. In other words, the dimensions of the impeller chamber control the length dimensions of the pump, and the PCA merely fits within the space defined thereby. Thus, in some examples the PCA fits within the minimum dimensional envelope of the micro-axial pump as defined by the other components thereof without adding to any of the pump's dimensions. In other words, the size of the pump may be essentially independent of the PCA, and therefore the pump may be made smaller than would otherwise be possible if the PCA were contributing to the dimensions of the pump.

In addition, in examples in which the PCA comprises two physically separate PCBs with connecting portions that extend across the flow path to couple together, this configuration can also facilitate easier assembly of the micro-axial pump. In particular, some examples of the pump may be configured with a stator that is split into two separate stator portions, which are assembled onto the impeller chamber by positioning the stator portions on opposite lateral sides of the impeller chamber and then laterally moving the two stator portions together, sandwiching the impeller chamber therebetween. Providing the PCA as two separate parts that join together around the flow path allows the PCA to be readily integrated into this assembly procedure of the stator onto the impeller chamber. For example, one PCB may be coupled to one of the stator portions and the other PCB may be coupled to the other stator portion before assembly of the stator portions together. As these two subassemblies (each pair of PCB and stator portion) are brought together around the impeller chamber, the electrical connecting portions of the PCBs may extend across the flow path and couple with one another. Thus, the connections between each PCB and corresponding stator part may be made while in a disassembled state, which simplifies the assembly process, and then the assembly of the PCBs together and the assembly of the stator portions together may be performed simultaneously as one action, thus further simplifying the assembly process.

Thus, examples disclosed herein may allow for micro-axial pumps to be produced which are smaller in size than would otherwise be possible, particularly in the height dimension, and some examples may also facilitate the easy assembly of these pumps.

Turning now to the figures, various devices, systems, and methods in accordance with nonlimiting aspects of the present disclosure will be described.

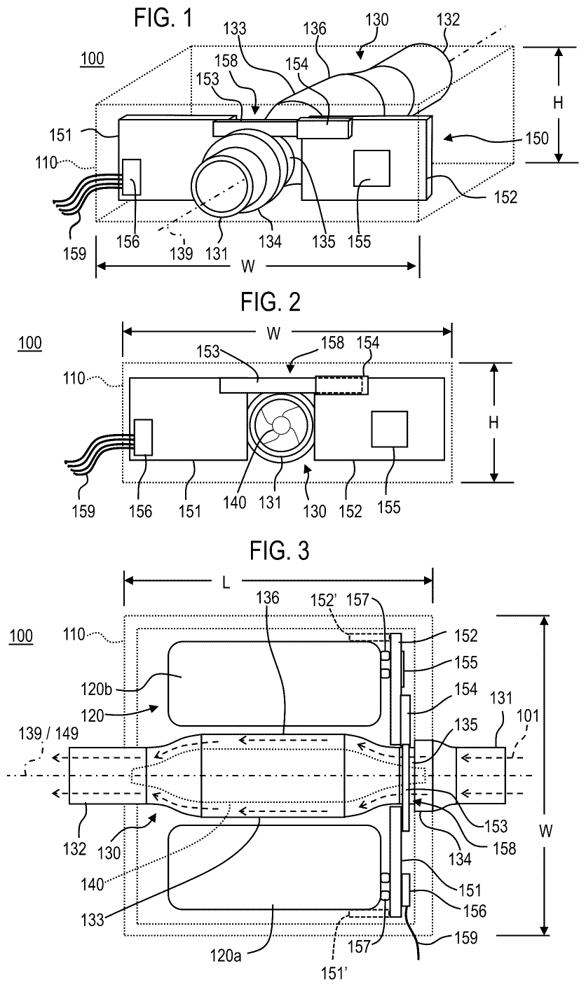

FIGS. 1-3 are schematic diagrams conceptually illustrating a pump 100. FIG. 1 comprises a schematic perspective view, FIG. 2 provides a schematic front view, and FIG. 3 provides a schematic top view. It should be understood that FIGS. 1-3 are not intended to illustrate specific shapes, dimensions, or other structural details accurately or to scale, and that implementations of the pump 100 may have different numbers and arrangements of the illustrated components and may also include other parts that are not illustrated.

As shown in FIGS. 1-3, the pump 100 comprises a housing 110, a motor stator 120 (also referred to herein as “stator 120”) (see FIG. 3), a conduit 130 defining a liquid flow path 101 (as shown by the dotted arrows flowing through the conduit 130), an impeller 140, and a split PCA 150 (also referred to herein as “PCA 150”). The housing 110 is shown as transparent in dashed lines to allow visibility of the other components. The impeller 140 is shown in dotted lines in FIG. 3 to indicate that it would be hidden in that view by the conduit 130 that surrounds the impeller 140. The components of the pump 100 will be described in greater detail below.

The motor stator 120 is configured to receive electrical power from the PCA 150 and in response generate alternating magnetic fields that interact with the impeller 140 to cause the impeller 140 to rotate about a rotation axis 149 thereof. The motor stator 120 may comprise wire windings or other electrically conductive materials to generate the magnetic fields and/or magnetically susceptible materials to transfer and distribute the generated fields around the impeller 140 in a desired pattern. A person of ordinary skill in the art would be familiar with motor stators that may be used as the motor stator 120.

In some examples, the motor stator 120 comprises two portions: a first stator portion 120a and a second stator portion 120b, as shown in FIG. 3. These two portions 120a and 120b are arranged on opposite lateral sides of the conduit 130. Reference is made to U.S. Ser. No. 11/015,608 B2, which describes example stators that comprise two portions and may be used as the motor stator 120.

The conduit 130 comprises walls that enclose a volume and define the liquid flow path 101 in that volume, with the liquid flow path 101 being the path along which liquid coolant (e.g., water or other coolants) flows as it traverses the pump 100. The conduit 130 comprises a pump inlet portion 131 (also referred to herein as “pump inlet 131”), a pump outlet portion 132 (also referred to herein as “pump outlet 132”), and an impeller chamber portion 133. The impeller chamber portion 133 houses the impeller 140 and is fluidically coupled to the pump inlet 131 and pump outlet 132. The pump inlet portion 131 and pump outlet portion 132 may comprise structures for fluidically coupling the pump with coolant lines of a liquid cooling loop, such as hose barbs, quick connect couplings, and/or other liquid coupling mechanisms as would be familiar to those of ordinary skill in the art. The conduit 130 may be liquid tight, sealing the interior volume from an exterior environment, other than at openings in the pump inlet 131 and pump outlet 132 that allow the enclosed interior volume to be fluidically coupled to the exterior environment (e.g., to coolant lines of a liquid cooling loop). In some examples, the pump inlet 131 and pump outlet 132 may extend outside of the housing 110 of the pump 100. In some examples, the impeller chamber portion 133 of the conduit 130 is contained within the housing 110.

In some examples, the impeller chamber 133 comprises an impeller chamber inlet portion 134 (also referred to herein as “impeller chamber inlet 134”) which is coupled to the pump inlet portion 131, an impeller chamber central portion 136 (also “central portion 136”), and a transition zone 135 between the impeller chamber inlet portion 134 and the impeller chamber central portion 136. In some examples, the impeller chamber 133 comprises an impeller chamber outlet portion (not labeled) which may be similar to the impeller chamber inlet portion 134 except coupled to the pump outlet portion 132, and a second transition zone (not labeled) between the impeller chamber outlet portion and the impeller chamber central portion.

The conduit 130 has a central longitudinal axis 139 extending along a length dimension L of the pump 100, and liquid flowing through the conduit 130 flows, as a whole, along directions parallel to the central longitudinal axis 139, as indicated by the dashed arrows representing the flow path 101 in FIG. 3 (portions of the liquid may occasionally flow at angles relative to the axis 139 along portions of the conduit 130, such as when the liquid is being moved around the impeller 140, but the bulk or average motion of the liquid as a whole in traversing the conduit 130 is along directions parallel to the axis 139). In some examples the liquid is present in the pump 100 only after the pump 100 has been deployed for use in a liquid cooling loop (e.g., coupled to coolant supply and return lines), while in other states (such as a state of the pump 100 upon manufacture), the liquid will not yet be present.

The impeller 140 is housed within the conduit 130, specifically in the impeller chamber 133 thereof, and is configured to rotate about a rotation axis 149 to drive liquid to flow along the flow path 101 through the conduit 130. The rotation axis 149 of the impeller 140 may also be a central longitudinal axis of the impeller 140, and these axes may also be aligned with the central axis 139 of the conduit 130. The impeller 140 may comprise, for example, blades that force the liquid axially along the flow path 101 through the conduit 130 as the impeller 140 rotates. The impeller 140 may be configured to rotate in response to the magnetic fields generated by the motor stator 120. For example, the impeller 140 may comprise permanent magnets and/or magnetically attractable (e.g., ferromagnetic) materials (e.g., iron, steel, etc.) which are arranged around the impeller 140 so as to interact with the magnetic fields generated by the motor stator 120 to produce rotation of the impeller 140. Thus, the impeller 140 and the motor stator 120 may together form an electromagnetic motor, with the impeller acting as the rotor portion of the motor. In some examples, the impeller 140 may comprise a tapered profile at the two opposite end portions thereof. In particular, in some examples a radius of the impeller 140 may be relatively small near the impeller chamber inlet portion 134, gradually increase throughout the transition zone 135, reach a maximum within the impeller chamber central portion 136, and then gradually decrease to another relatively small radius near an outlet side of the impeller chamber 133. A person of ordinary skill in the art would be familiar with impellers, and thus the impeller 140 is not described in greater detail herein.

As described above, the PCA 150 is arranged to straddle the conduit 130, with the PCA 150 being transvers to the flow path 101 (i.e., transverse to the rotation axis 149 of the impeller 140 and to the longitudinal axis 139). Straddling the conduit 130 and/or flow path 101, as used herein, refers to the PCA 150 having two primary PCA portions 151 and 152 that are disposed on opposite lateral sides of the conduit 130/flow path 101, with these two primary portions 151 and 152 being electrically connected together by one or more connecting portions 158 that extend across (over and/or under) the conduit 130/flow path 101. Herein, references to “lateral” should be understood as referring to directions parallel to a width dimension W of the pump 100 as illustrated in FIGS. 1-3, which is perpendicular to the axes 139 and 149 and the flow path 101. As used herein, “transverse” refers to a positional relationship of two items in which one item is oriented crosswise at an angle relative to the other item, such as being substantially or generally perpendicular to the other item. As used herein, “transverse” includes, but does not require, an exactly perpendicular relationship. As used herein, the PCA 150 being transverse (e.g., perpendicular) to the flow path 101 or axes 149/139 means that the broadest faces of the two primary portions 151 and 152 of the PCA 150 that straddle the flow path 101 are transverse (e.g., perpendicular) to the flow path 101 or axes 149/139. In other words, the PCA 150 is arranged such that the broadest faces of the two primary portions 151 and 152 straddling the flow path are approximately parallel to a plane defined by the height H and width W dimensions of the pump 100 as illustrated in FIGS. 1-3. However, it should be understood that the PCA 150 could optionally include any number of additional portions, referred to herein as secondary portions 151′ and/or 152′, which are not necessarily arranged perpendicular to the flow path 101 or axes 149/139. For example, secondary portions 151′ and/or 152′ may comprise PCBs that are coupled to the primary portions 151 and/or 152 at right angles and thus which extend parallel to the flow path 101 and axes 149/139. In addition, each PCA portion or PCB referred to herein may itself comprise multiple sub-portions, such as multiple boards stacked atop one another, for example. The PCB(s) that make up the PCA 150 may be ridged or flexible.

In some examples, the PCA 150 comprises two separate and distinct PCBs (or PCAs) that form the primary PCA portions 151 and 152, which are disposed on opposite lateral sides of the conduit 130. Thus, in relation to those examples the primary portions 151 and 152 may also be referred to herein as PCBs 151 and 152. In other examples (not illustrated), the PCA 150 the primary PCA portions 151 and 152 are two portions of a single PCB that is shaped to allow the PCB to straddle the conduit 130 with two portions thereof disposed on opposite sides of the conduit 130—for example, a hole or notch may be provided in a middle region of the PCB through which the conduit 130 may extend.

In examples in which the PCA 150 comprises two separate PCBs 151 and 152, each connecting portion 158 of the PCA 150 that connects the two PCBs 151 and 152 together may comprise an electrical transmission pathway that electrically couples the PCBs 151 and 152 together, wherein the electrical transmission pathway may comprise wires, cables, electromagnetic couplers (e.g., transformers), and/or connectors, for example.

In some of these examples, these electrical transmission pathways of the connecting portion(s) 158 may comprise paired electrical connectors 153 and 154 that are configured to removably mate together to establish the electrical connection that allows electrical power and/or communication signals to pass between the PCBs 151 and 152. In other words, in these examples each connecting portion 158 comprises at least two separable parts: at least one connector 153 and at least one corresponding connector 154. As there could be multiple connecting portions 158 in some examples, and as each connecting portion 158 could have multiple pairs of connectors 153 and 154, the number of connectors 153 and 154 may vary from one implantation to the next, including one pair of connectors 153 and 154 in some examples, two pairs of connectors 153 and 154 in some example, three pairs of connectors 153 and 154 in some examples, four pairs of connectors 153 and 154 in some examples, and five or more pairs of connectors 153 and 154 in some examples. The first connector(s) 153 are coupled to the first PCB 151 and the second connector(s) 154 are coupled to the second PCB 152. In some examples, the connectors 153 and 154 are blind mate connectors, which have guide features configured to allow for coupling even when the connectors 153 and 154 are slightly misaligned initially by guiding the connectors 153 and 154 into proper alignment as the connectors come together. Such blind mate connectors may make assembly of the pump easier, as when the two PCBs are brought together around the conduit 130 perfect alignment between the connectors 153 and 154 may not be needed. In some nonlimiting examples, the connectors 153 and 154 comprise blind-mate TermiMate connectors. One advantage of utilizing two distinct PCBs 150 that have removably connectable connectors 153 and 154 is that assembly of the pump 100 may be greatly simplified thereby, as will be explained in greater detail below after other aspects of the PCA 150 have been described.

In other examples, in which the PCA 150 comprises two separate PCBs 151 and 152, the electrical transmission pathways that form the connecting portion(s) 158 may comprise permanent or semi-permanent electrical connections extending between the two PCBs 151 and 152, instead of removably mated connectors. For example, a wire or cable may form part of a connecting portion 158 and may extend between the two PCBs 151 and 152, with the ends of the wire/cable being permanently affixed to the PCBs 151 (e.g., by solder, crimping, etc.) or semi-permanently affixed to the PCBs 151 (e.g., by a lug nut or other mechanical fastener). Permanent here means that one or more parts may need to be damaged or dismantled to remove the part (e.g., such as by removing solder), but does not imply an impossibility of removing the part. Semi-permanent here means that some form of non-destructive disassembly is required other than simply moving the connectors together or apart, such as the removal of lug nuts for example. These are both contrasted with a removable connection which allows for connection or disconnection by simply moving the two parts together or apart (in some examples also involving the actuation of a button or lever to disengage a latch).

In other examples in which the PCA 150 comprises a unitary PCA with two lateral PCB portions arranged on opposite lateral sides of the conduit 130, the one or more connecting portions 158 may comprise intermediate portions of the PCA that extend between the two PCB lateral portions. In these examples, connectors (like the connectors 153 and 154) may be unnecessary as electrical signals may be carried from one side of the PCA 150 to the other via conductive traces extending through the portion of the PCB that extends across the conduit 130. To allow the PCA 150 in these examples to straddle the conduit 130, a portion of the PCB that forms the PCA 150 may be removed or omitted during manufacture to form a hole or notch through which the conduit 130 may be routed while two portions of the PCB are positioned on opposite lateral sides thereof.

Returning to those examples in which the two portions of the PCA 150 comprise two separate PCBs 151 and 152, in some examples the connecting portion(s) 158 may include not only connectors 153 and 154 (and/or wires or cables) but also portions of the PCB 151 and/or 152 that protrude from the remainder thereof and extend at least partially across the conduit 130. In other examples each of the protruding portion(s) of the PCB 151 and/or 152 extends fully across the conduit 130. For example, in some implementations, just one of the PCBs 151 or 152 includes one or more protruding portions that extend fully or partially across (e.g., over, under, or both over and under) the conduit 130. As another example, in some other implementations, the protruding portion of one PCB 151 or 152 extends over and fully across the conduit 130 while the protruding portion of the other PCB 152 or 151 extends under and fully across the conduit 130. In other examples that include a protruding portion of the PCB 151 and/or 152, the protruding portions extend partially across the conduit 130, with the connectors 153 and 154, wires/cables, and/or the protruding portion of the other PCB 151 or 152 extending the remainder of the way across the conduit 130. For example, in some implementations both PCBs 151 and 152 have one or more protruding portions that extend partially over (or partially under) the conduit, meeting somewhere in the middle.

In addition to (or in lieu of) the protruding portions of the PCBs 151 and 152 extending across the conduit 130, in some implementations one or both of the connectors 153 and/or 154 may extend fully or partially across the conduit 130. However, in some other examples the connectors 153 and 154 may be positioned entirely laterally of the conduit 130, with only the protruding portion(s) of the PCB 151 and 152 and/or wires extending across the conduit 130.

In FIGS. 1-3, one connecting portion 158 comprising one electrical transmission pathway (e.g., a pair of connectors 153 and 154) is illustrated, but in practice any number of connecting portions 158 and electrical transmission pathways can be provided, subject to there being available space for these (which will depend on the implementation). More electrical transmission pathways may be desired in cases where it is desired to have more data communication lines. In particular, in some examples, two connecting portions 158 are provided, with one connecting portion 158 passing over the conduit 130 and the other connecting portion 158 passing under the conduit 130. In some of these examples in which two connecting portions 158 are provided, these may include two pairs of connectors 153 and 154, each pair corresponding to one of the connecting portions 158. In other examples, four electrical transmission pathways may extend across the conduit 130, i.e., two extending over and two extending under. For example, if these four electrical transmission pathways each comprise a pair of connectors 153 and 154, then two connectors 153 may be connected to a front side of the PCB 151 (one for the path extending over the conduit 130, one for the path extending under the conduit 130), two additional connectors 153 are coupled to a back side of the PCB 151 (again, one for each of the paths), and then the four corresponding connectors 154 may be similarly disposed on the PCB 152 (two on the front, two on the back). Front as used here refers to the faces of the PCBs 151 and 152 that face the pump inlet 131 and back refers to the opposite faces of the PCBs 151 and 152 (e.g., the faces that face the pump outlet 132). Additionally, if space allows, multiple connectors 153/154 may be disposed adjacent to one another on the same side of the PCBs 151 and 152 with both extending over the conduit 130 or both extending under the conduit 130.

As shown in FIGS. 1-3, the PCA 150 may comprise a connection terminal 156 that is coupled to, or configured to be coupled to, electrical transmission lines 159 (e.g., wires or cables) to provide electrical power and data signals to the PCA 150. In some example, the connection terminal 156 comprises an electrical connector for removably connecting with a complementary connector of the electrical transmission line 159. In other examples, the connection terminal 156 is permanently or semi-permanently coupled to the electrical transmission line 159 (or is configured to be so coupled), for example via soldering or mechanical fasteners. The connection terminal 156 is illustrated on the PCB 151, but it could be disposed on other either of the PCBs 151 or 152.

The PCA 150 may also comprise one or more electrical components 155 that control operations of the pump 100. In some examples the electrical components 155 comprise control circuitry configured with logic to drive operations of the pump 100. For example, control circuitry may include a microcontroller. As another example, the control circuitry may include discrete logic circuits (digital or analog), in addition to or instead of a microcontroller. The electrical components 155 may also include sensors, such as temperature sensors, electrical power usage sensors, moisture sensors (e.g., for leak detection), or other sensors. In some examples the PCA 150 may carry a magnetic field sensor, such as a Hall effect sensor. Such a magnetic field sensor may be particularly useful, for example, to sense the magnetic fields generated by the stator 120, which may be used as feedback to the control circuitry to assist the control circuitry in controlling the stator 120. In some examples, a portion of one of the PCBs 151 or 152 extends across the conduit and the Hall effect sensor may be coupled to the PCB 151 or 152 on that portion that extends across the conduit. This may allow the Hall sensor to be positioned near or at a position that is over (or under) the central axis 139, which may be useful (or even necessary, in some cases) for optimally controlling the stator 120. The electrical components 155 may also include power delivery components, such as transistors or other switches (e.g., relays), capacitors, diodes, etc. In some examples, the electrical components 155 may include an RFID chip, a communication bus (e.g., an I2C bus), or other communications components for communicating with outside devices for example via the electrical transmission lines 159 and/or wirelessly (via, e.g., Bluetooth, WiFi, etc.). Examples of some outside devices that the PCA 150 may communicate with may include things such as a system controller, baseboard management controller (BMC), a rack controller, or any other external device. Information communicated between the PCA 150 and the external device may include things such as PWM control input signals (e.g., for the external device to instruct the pump 100 at what speed to operate), tachometer output signals (e.g., for the pump 100 to inform the external device of the impeller speed), pump information signals (signals communicating serial numbers, runt time, etc.) system status signals, pump status signals, or other signals. In some examples, electrical components such as the electrical components 155 are provided on only one of the primary PCA portions 151 and 152, and the other one of the primary portions 152 and 151 has only conductive traces and terminals/connectors for electrically coupling these conductive traces to the other PCB portion 151 or 152 or to other components such as the stator 120. In other words, in some examples, one of the primary portions 151 and 152 is active while the other primary portion 152 or 151 is passive.

The PCA 150 may also comprise coating layers, such as an epoxy coating for example, to make the PCA 150 water resistant (e.g., IP65 rated). In other examples, the entire housing 110 may be filled with epoxy or another filling to ensure water tightness of all components thereof. In some examples, the entire housing 110 may be filled, for example, with thermal epoxy (epoxy that is thermally conductive when cured), which may facilitate the dissipation of heat from the PCA 150 and the motor stator 120 into the liquid coolant flowing through the conduit 130 by filing in air gaps and thermally coupling these components together.

The PCA 150 may be electrically and physically connected to the motor stator 120, for example via electrical connections 157. The electrical connections 157 may comprise, for example, solder that is applied to electrical contacts on the PCA 150 (e.g., on the back faces of the primary PCA portions 151 and 152) and to the stator 120 (e.g. to wire coils of the stator 120) such that the solder directly couples the two together, wires permanently or semi-permanently coupled to both the stator 120 and the PCA 150, paired electrical connectors removably coupled to the stator 120 and the PCA 150, or any other desired electrical connections. In some examples, the primary PCA portion 151 is coupled to part of the stator 120 by one set of electrical connections 157 and the primary PCA portion 152 is be coupled to another part of the stator 120 by another set of electrical connections 157—for example, in some implementations in which the motor stator 120 comprises two distinct stator portions 120a and 120b, the portion 151 may be coupled to the stator portion 120a and the portion 152 may be coupled to the stator portion 120b.

In some examples, in which the PCA 150 comprises distinct PCBs 151 and 152 and the stator comprises distinct stator portions 120a and 120b, the PCBs 151 and 152 may be electrically coupled (e.g., soldered) to the stator portions 120a and 120b prior to assembling the two stator portions together. This may simplify the coupling of the PCA 150 to the stator 120, as the coupling may be performed in an unassembled state, which allows easier access to the portions that need coupling and/or more room to maneuver tools (e.g., a soldering iron) that are used in the coupling. In contrast, attempting to join the PCA 150 to the stator 120 after the stator 120 is assembled around the conduit 130 could be more difficult, given the tight spaces and small parts involved. Thereafter, the subassemblies comprising the two stator portions 120a and 120b with the PCBs 151 and 152 coupled respectively thereto may be positioned on opposite lateral sides of the conduit 130 and then brought together by moving the two subassemblies laterally toward the conduit 130, sandwiching or capturing the conduit 130 between the two subassemblies. In examples in which the PCA 150 comprises connectors 153 and 154, the process of bringing the two subassemblies together around the conduit 130 also causes the pairs of connectors 154 and 154 to mate with one another. This can further simplify the manufacturing process, as it is not necessary to manually join (e.g., solder) electrical connections between the PCBs 151 and 152 when they are in an installed state around the conduit 130, which could be difficult given the limited space and the small parts involved.

The electrical connection 157 between the PCA 150 and the motor stator 120 may allow the PCA 150 to supply electrical power to the windings of the motor stator 120 to generate the magnetic fields. At least some of this electrical power may flow through the connecting portions 158 described above (e.g., via the connectors 153 and 154, in some examples) before being passed through the connections 157 to the stator 120. The PCA 150 may be configured to supply this electrical power to the motor stator 120 at the appropriate timings and with the appropriate waveforms needed to generate the desired pattern of magnetic fields that will cause rotation of the impeller 140. In other words, the signals passed from the PCA 150 to the stator 120 may not only power but may also directly control the stator 120. In other examples, the stator 120 has its own internal control circuitry (not illustrated) that controls lower-level functions of the stator 120 (such as modulating the magnetic fields), and the PCA 150 may thus indirectly control the stator 120, for example, by providing instructions or requests to the internal control circuitry of the stator 120.

In some examples, the PCA 150 is arranged to straddle the flow path at and around the transition zone 135 of the impeller chamber 133. As noted above, this transition zone 135 may be located between the inlet portion 134 of the impeller chamber 133 and the central portion 136 of the impeller chamber 133, and there may be an open volume in this region in which the PCA 150 can fit without necessitating increasing any dimensions of the pump 100. The transition zone 135 may have a smaller outer radius than the impeller chamber inlet portion 134 and the central portion 136, and this may allow the connecting portions 158 of the PCA 150 sufficient room to extend across the conduit 130 without needing to increase a height of the pump 100. For example, if the radius of the conduit 130 at the transition zone 135 is R and the height of the pump 100 is H, then there may be a space (H-R)/2 high above the transition zone 135 and similarly another space (H-R)/2 high below the transition zone 135 through which the connecting portions 158 of the PCA 150 may extend.

The impeller chamber inlet portion 134 may have a larger outer radius than the transition zone 135 because the impeller chamber inlet portion 134 may be located at, and form a portion of, a wall of the housing 110 and thus may include additional structural components arranged radially around the flow path 101. The central portion 136 may have a larger outer radius because it may contain a portion of the impeller 140 that comprises the magnets. In addition, the impeller 140 may be shaped to increase in radius along the flow path to allow for optimal pumping performance, as described above, and this also contributes to the larger radius of the central portion 136. The transition zone 135, on the other hand, does not need to have a larger outer radius or other components disposed around it, and thus the space around the transition zone 135 of the conduit 130 may be well-suited for the PCA 150 to be disposed in some examples.

In some examples, the PCA 150 does not affect any of the dimensions of the pump 100. For example, because the PCA 150 is not stacked on top of the stator 120 and/or housing 110 in the height dimension H, the thickness of the PCA 150 does not contribute to the height of the pump 100. In addition, given the sizes of stators 120 and conduits 130 that are used in current designs, the PCA 150 can be manufactured with a width and length that allows it to fit, when oriented as shown in FIGS. 1-3, within an envelope defined by the height H and width W of the stator 120 and/or conduit 130. Thus, the overall height H and width W of the pump 100 are dependent on the dimensions of the stator 120 and the conduit 130, but the PCA 150 does not contribute to the height or width dimensions H and W. Moreover, the length dimension L of the pump 100 is dependent entirely on the length of the conduit 130, which depends on the performance requirements of the impeller 140. For example, the impeller chamber inlet portion 134 and the impeller chamber central portion 136 are separated by a particular distance along the length dimension L to provide optimal performance of impeller 140. As a result of this separation, the open space between the impeller chamber inlet portion 134 and the impeller chamber central portion 136 would be present regardless of whether it is occupied by the PCA 150 or not. Because the thickness of the PCA 150 is less than the separation distance between the impeller chamber inlet portion 134 and the central portion 136, the positioning of the PCA 150 does not necessitate an increase in the length dimension L. Thus, in some examples the dimensions of the pump 100 are independent of the PCA 150, allowing for the pump 100 to be made as small as is possible in view of the other components thereof. In other words, the pump 100 can be made smaller than it otherwise could be if the PCA 150 were arranged differently, such as by being stacked on the stator 120 or housing 110.

In the description above, the PCBs 151 and 152 are described as if they each comprised a single PCB, for ease of description. However, in some examples, one or both of the PCBs 151 and 152 may comprise multiple PCBs coupled together (e.g., stacked in layers). This has no effect on the subject matter described above other than potentially increasing the overall thickness of the PCA 150. However, in some examples there is sufficient room to allow for this thickness without affecting the overall dimensions of the pump 100. In examples in which one or both of the PCBs 151 and 152 comprise multiple PCBs coupled together, they may also be referred to as PCAs (e.g., the split-PCA 150 may be said to comprise two distinct PCAs). However, in general use of “PCB” herein should be understood as broadly encompassing either a single PCB or multiple PCBs coupled together unless it is specified otherwise or would be logically contradictory in the context.

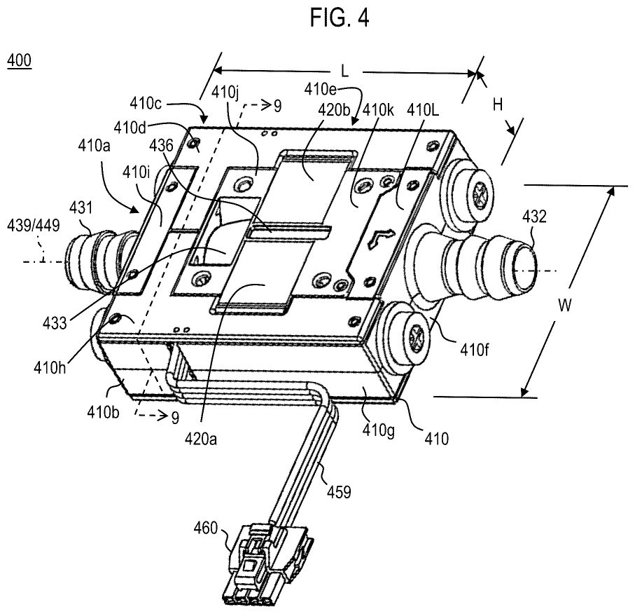

Turning now to FIGS. 4-9, another example pump will be described, in the form of pump 400. The pump 400 is an example configuration of the pump 100 described above. Thus, some components of the pump 400 are similar to (e.g., example configurations of) corresponding components already described above, and thus the descriptions of the components of the pump 100 above are applicable to the similar components of the pump 400, and duplicative descriptions of certain aspects of the pump 400 may thus be omitted. Corresponding components may be referred to using reference numbers having the same last two digits, such as 110 and 410. It should be understood that the pump 400 is but one possible configuration of the pump 100, and the pump 100 is not limited to the pump 400. Similarly, the individual components of the pump 400 are examples of the corresponding individual components of the pump 100, but the individual components of the pump 100 are not limited to the corresponding components of the pump 400.

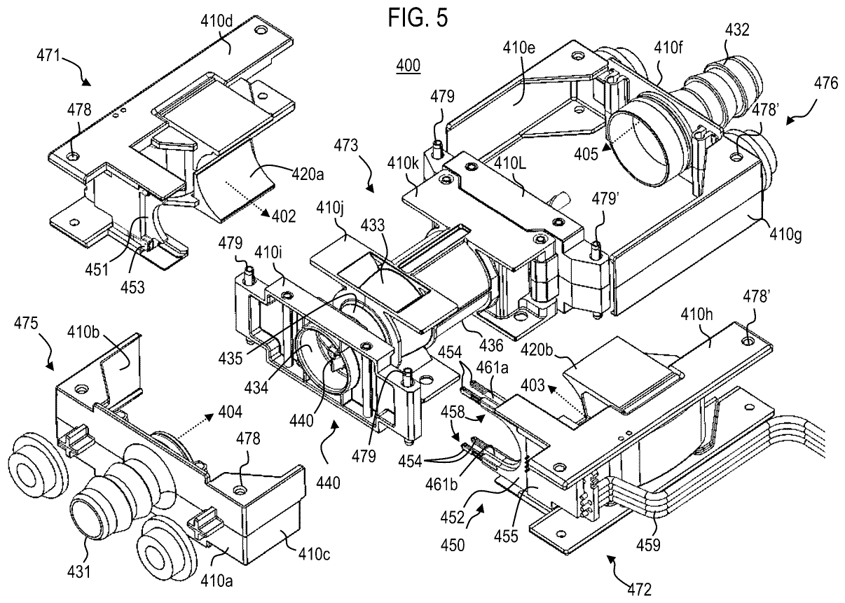

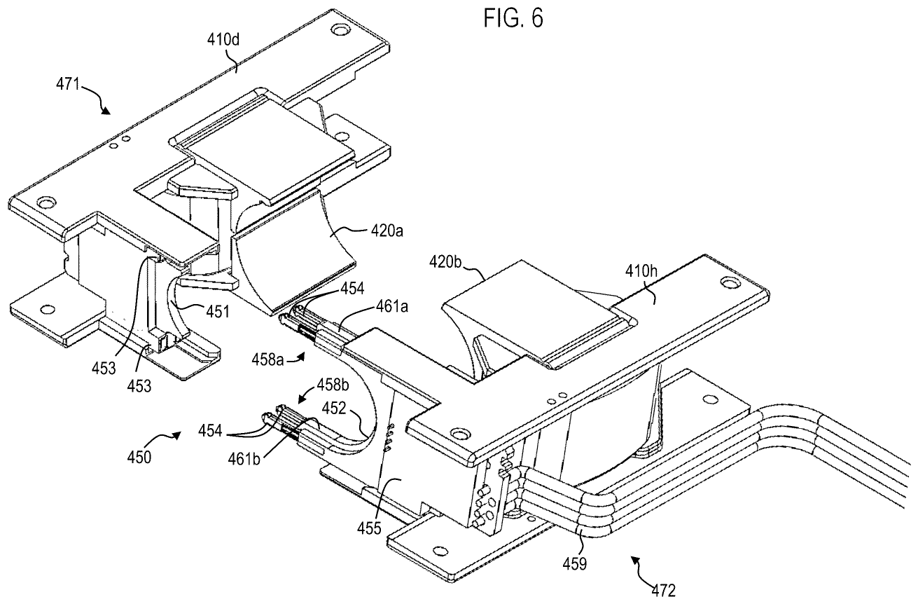

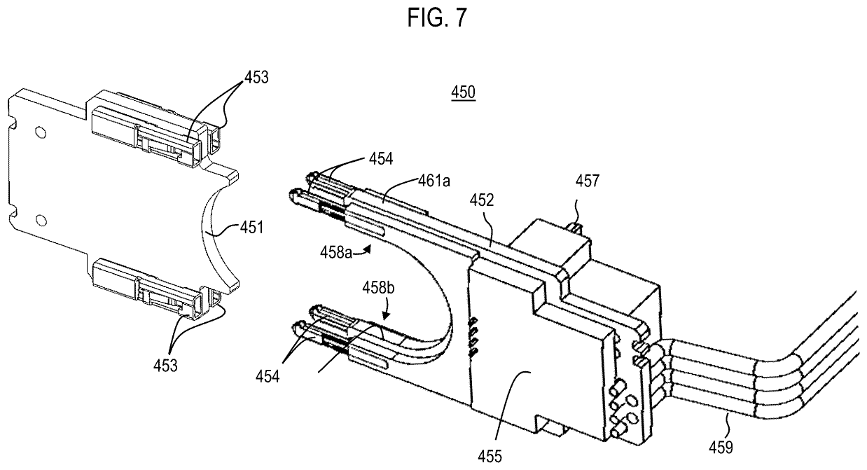

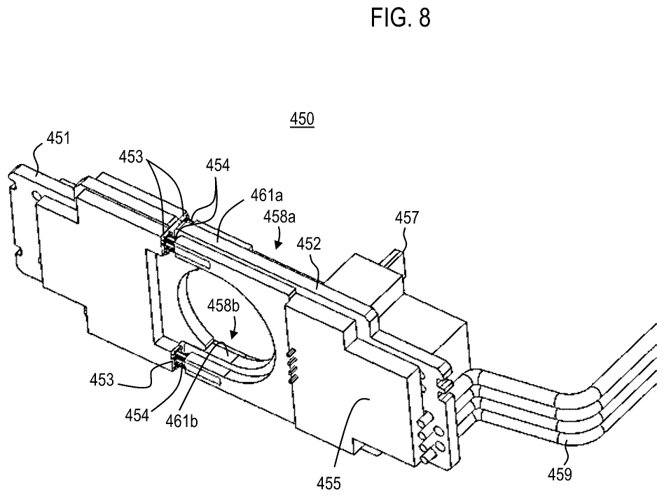

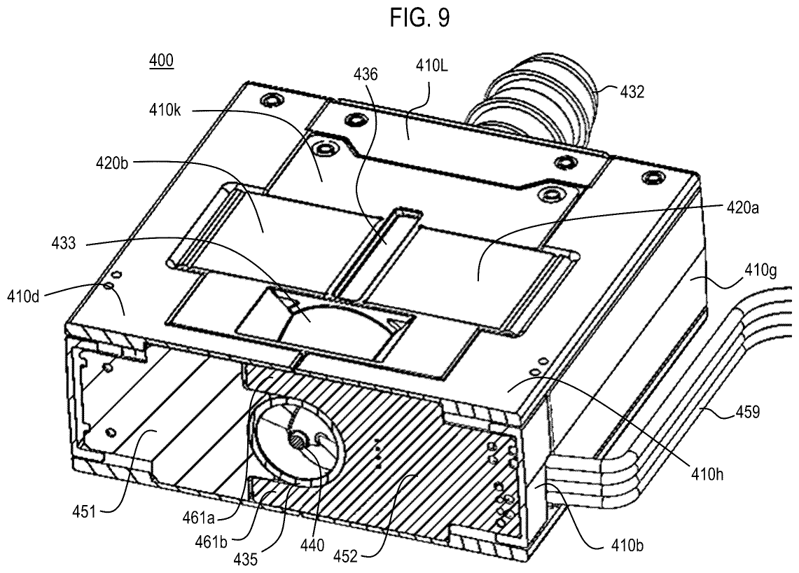

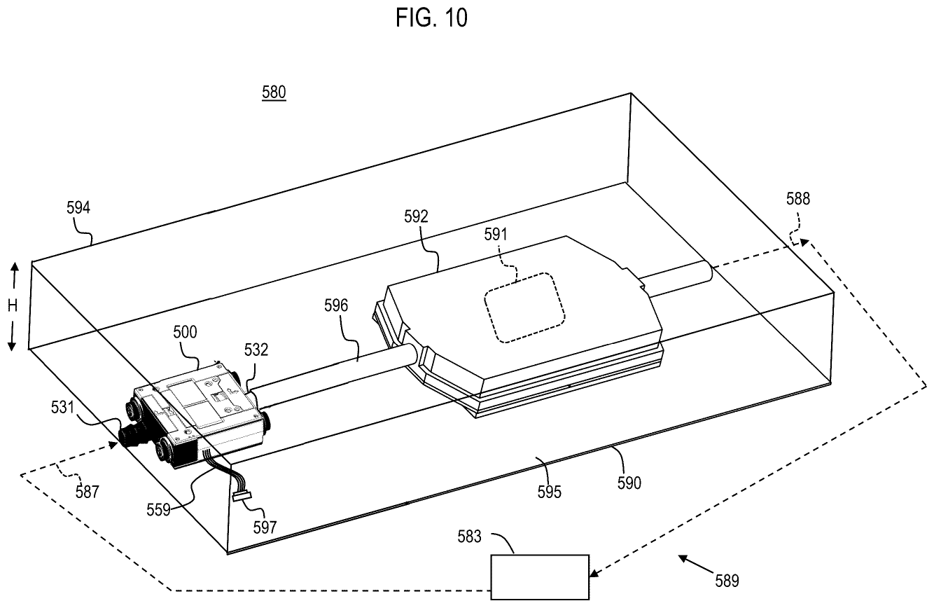

Various aspects of the pump 400 are visible in multiple figures, and different figures may show certain aspects better than others. Thus, rather than describing each of FIGS. 4-9 below in strict sequence, the various aspects of the pump 400 will be described in turn below with reference to figures that are relevant to the particular aspect under discussion. FIGS. 4 and 5 show the pump 400 in perspective and exploded views, respectively; FIG. 6 shows a portion of the pump 400 comprising first and second stator subassemblies 471 and 472; FIG. 7 shows a portion of the pump 400 comprising the split PCA 450 in an unassembled state; FIG. 8 shows the split PCA 450 in an assembled state; and FIG. 9 comprises a cross-section of the pump 400 taken along the plane 9-9 in FIG. 4.

As shown in FIG. 5, the pump 400 comprises a number of subassemblies, including a first stator subassembly 471, a second stator subassembly 472, an impeller subassembly 473, an inlet subassembly 475, and an outlet subassembly 476. Each of these subassemblies will be described in greater detail below.

As shown in FIGS. 5 and 6, the first and second stator subassemblies 471 and 472 comprise first and second stator portions 420a and 420b, respectively. In addition, the first and second stator subassemblies 471 and 472 comprise the first and second PCBs 451 and 452, respectively, which make up the split PCA 450. The first and second PCBs 451 and 452 are electrically coupled, for example via solder or other electrical connections 457, to the first and second stator portions 420a and 420b, respectively. As noted above, in some examples the first and second PCBs 451 and 452 may be coupled to the first and second stator portions 420a and 420b prior to assembly of the pump 400, which may make manufacture of the pump 400 much easier. As shown in FIG. 5, the first and second stator subassemblies 471 and 472 are positioned on opposite lateral sides of the impeller subassembly 473. Thus, during assembly of the pump 400 the first and second stator subassemblies 471 and 472 may be positioned as shown in the exploded view of FIG. 5 and then the stator subassemblies 471 and 472 may be moved laterally (along directions indicated by arrows 402 and 403) to bring the stator subassemblies 471 and 472 together around the impeller subassembly 473. Once so assembled, the stator portions 420a and 420b are positioned adjacent to and radially surround the impeller chamber central portion 436 (except for small regions at the top and bottom of the central portion 436, which are not surrounded). Moreover, as the first and second stator subassemblies 471 are coupled to the impeller subassembly 473, the first and second PCBs 451 and 452 become electrically coupled tougher (see FIG. 8) via mating of the connectors 454 and 453, as will be described further below.

As shown in FIG. 5, the impeller subassembly comprises the impeller chamber 433 and the impeller 440 housed within the impeller chamber 433. The impeller chamber 433 comprises an impeller chamber inlet portion 434, a transition zone 435, an impeller chamber central portion 436, and an impeller chamber outlet portion (not visible). The impeller chamber 433 is also coupled to various support structures that form part of the housing 410 and which facilitate joining of the other subassemblies together, as described below. The impeller 440 is configured to rotate about a rotation axis 449, as described above in relation to the impeller 140.

The inlet subassembly 475 comprises the pump inlet 431 and vibration isolators 466. The outlet subassembly 476 comprises the pump outlet 432 and vibration isolators 466. In the illustrated example, the pump inlet 431 and pump outlet 432 comprise hose barb couplings. In other examples, other types of liquid couplings may be substituted for the hose barb couplings. The pump 400 may be coupled to another device (e.g., a chassis of a computing device that the pump 400 is disposed within) via the vibration isolators. The vibration isolators 466 may be rubber, silicon, or another compliant material that helps to absorb vibrations generated by the pump 400 and prevent (or reduce) the transmission of these vibrations to the device in which the pump 400 is disposed. In addition, each of these subassemblies 475 and 476 comprises portions of the housing 410. As shown in FIG. 5, the inlet and outlet subassemblies 475 and 476 may be positioned on opposite axial sides of the impeller subassembly 473. Thus, during assembly of the pump 400 the inlet and outlet subassemblies 475 and 476 may be positioned as shown in FIG. 5 and then moved towards one another (along directions indicated by arrows 404 and 405) until the pump inlet 431 is fluidically coupled with one side of the impeller chamber 433 and the pump outlet 432 is fluidically coupled with the other side of the impeller chamber 433. In some examples, this assembly step may occur after the two stator subassemblies 471 and 472 have been assembled onto the impeller subassembly 473. Once the pump inlet 431, pump outlet 432, and impeller chamber 433 are coupled together, they form the conduit 430 through which liquid coolant may flow along a central axis 439 thereof.

As shown in FIGS. 4 and 5, the pump 400 comprises a housing 410. This housing 410 may be made up of multiple portions that are joined together. Specifically, the subassemblies described above may comprise these portions of the housing 410. In particular, the housing 410 comprises inlet end wall portion 410a and lateral wall portions 410b and 410c coupled to inlet end wall portion 410a. These portions 410a-c are part of the inlet subassembly 475. The housing 410 further comprises outlet end wall portion 410f and lateral wall portions 410g and 410e. These portions 410e-g are part of the outlet subassembly 476. When assembled, the aforementioned portions 410a-c and 410e-g define the perimeter side walls of the housing 410. The housing 410 also comprises top portion 410d which is coupled to the first stator portion 420a and part of the first stator subassembly 471, and top portion 410h which is coupled to the second stator portion 420b and part of the second stator subassembly 472. The housing also comprises top housing portions 410i, 410j, 410k, and 410L which are coupled to the conduit 430 and are part of the impeller subassembly 473. The top portions 410d, 410h, and 410i-410L form the top face of the housing 410. Note that the top face of the housing 410 is not necessarily uniform and does not necessarily fully cover all of the pump 400. For example, a top of the stator portion 420a and 420b may be exposed and approximately coplanar with the top face of the housing 410 (this may allow the height dimension H of the pump 400 to be reduced to the absolute minimum possible for a given size of stator 420). Some of the housing portions may include holes 478 (only some are labeled) that are arranged to receive a fastener 479 to couple the subassemblies together. For example, in some implementations including the one illustrated in FIG. 5, the impeller subassembly 473 comprises fasteners 479 in the form or pins, such as spring-biased push pins, and each of these may be inserted into holes 478 of one more the subassemblies to secure the respective subassemblies together. A single fastener 479 may be inserted through two holes 478 of two different subassemblies—for example, the fastener labeled 479′ in FIG. 5 may be inserted into the two holes labeled 478′ which are part of the stator subassembly 472 and the outlet subassembly 476. The other fasteners 479 and holes 478 may be similarly joined.

The bottom portion of the housing 410 (which is generally not visible in the figures and is not labeled herein) may be similarly constructed as the top portion thereof, and thus duplicative description of these portions is omitted.

As shown in FIGS. 5-9, the pump 500 also comprises a split PCA 450, which is one example configuration of the PCA 150 described above. The PCA 450 is configured to straddle the conduit 430 and the fluid flow path defined thereby. Specifically, the PCA 450 comprises two distinct PCBs 451 and 452, which are arranged on opposite lateral sides of the conduit 430, and multiple connecting portions 458 extend across the conduit 430/flow path to electrically couple the PCBs 451 and 452 together. As best seen in FIG. 7, in the illustrated example the connecting portions 458 of the PCA 450 comprise two protruding portions 461a and 461b from the PCB 452, which protrude over and under, respectively, the conduit 430/flow path. In addition, the connecting portions 458 comprise four pairs of electrical connectors 453 and 454. The electrical connectors 454 are male connectors, such as pins, and are coupled to the PCB 452. The connectors 453 are female connectors, such as sockets or receptacles, and are coupled to the PCB 451. The connectors 453 and 454 are coupled to both front and back sides of the PCBs 451 and 452. FIGS. 6 and 7 illustrated the PCBs 451 and 452 in an uncoupled state, such as may occur when the stator subassemblies 471 and 472 are positioned on opposite sides of the impeller subassembly 473 in preparation for assembly thereof. FIGS. 8 and 9 illustrate the PCBs 451 and 452 in a coupled state, such as may occur when the pump 400 has been assembled. As shown in FIG. 9, when the pump 400 is assembled the protruding portions 461a and 461b of the PCB 452 extend over and under the conduit 430, respectively. Although four pairs of connectors 453 and 454 are illustrated, this is just an example and in practice other numbers of pairs of connectors 453 and 454 could be used within the pump 400, such as one pair, two pairs, three pairs, or more pairs.

As shown in FIG. 6-8, the PCA 450 may also comprise electrical components 455 and may be coupled to electrical transmission line 459, as described above in relation to the PCA 150 (duplicative description of these components is thus omitted). As shown in FIG. 4, in some examples, the electrical transmission line 459 may be coupled to a connector 460 to allow the pump 400 to be coupled to another device from which it may receive power and/or communications. For example, the connector 460 may allow the pump 400 to be connected to a baseboard (motherboard) of a computing system that the pump 400 is to be disposed within to deliver liquid cooling thereto.

As shown in FIGS. 5 and 9, the PCA 450 straddles the conduit 430/flow path at a location corresponding to the transition zone 435 of the impeller chamber 433. As shown in FIG. 5, the transition zone 435 is a portion of the impeller chamber 433 that is located between the impeller chamber inlet 434 and the impeller chamber central portion 436. The impeller chamber inlet 434 is surrounded by various structural support features that make up part of the housing 410 and/or facilitate coupling together of the various subassemblies, and thus there is no room for the PCA 450 to straddle the conduit 430 around the impeller chamber inlet 434. Similarly, the central portion 436 comprises housing portions 410j and also is abutted by the stator portions 420a and 420b, and thus there is no room around the central portion 436 for the PCA 450. However, as shown in FIGS. 5 and 9, the transition zone 435 may have sufficient open space on either lateral side thereof for the PCBs 451 and 452 to be disposed there. Moreover, as shown in FIGS. 5 and 9 there is also sufficient space above and below the transition zone 435 through which the connecting portions 458 may extend. Thus, the disposition of the PCA 450 straddling the transition zone 435 may allow for the PCA 450 to fit within an envelope of the pump 400 without contributing to an increase in any of the dimensions of the pump 400.

FIG. 10 comprises a schematic diagram illustrating an example system 580 and electronic device 590. The system 580 comprises the electronic device 590 and a liquid cooling loop 589 coupled to the electronic device 590. The system may also comprise additional electronic devices (not illustrated). For example, the system 580 may comprise a rack or plurality of racks of electronic devices. The electronic device 590 is illustrated in a state of being installed in the system 580 for convenience of description, but it should be understood that the electronic device 590 may be provided separate from the system 580.

The liquid cooling loop 589 comprises the pump 500 (described below), one or more coolant supply lines 587, one or more coolant return lines 588, and one or more additional cooling loop components 583 such as a heat exchanger, rack-, row-, or datacenter-level coolant distribution unit(s), a chiller, or other cooling components that would be familiar to those of ordinary skill in the art.

The electronic device 590 comprises a PCB 595, such as a baseboard or motherboard of a computing device, and a chassis 594 supporting and housing the PCB 595. The PCB 595 comprises a heat generating component 591, such as a processor, power supply unit, memory device, hardware accelerator, or any other heat generating component. The electronic device 590 further comprises a cold plate 592 thermally coupled to the heat generating component 591.

The electronic device 590 further comprises a pump 500 disposed with in the chassis 594. The pump 500 may be any of the pumps described above, such as the pump 100 and the pump 400. The pump 500 is fluidically coupled with the cold plate 592 via coolant line 596. The pump 500 is electrically connected to the PCB 595 via an electrical transmission line 559 (e.g., one or more wires and/or cables) connected to connector 598 of the PCB 595. Thus, the PCB 595 can supply power to and/or communicate with the pump 500. The pump 500 comprises a pump inlet 531 that may be coupled to the liquid coolant supply line 587 of the liquid cooling loop 589 of the system 580, which supplies liquid coolant to the pump 500. A pump outlet 532 of the pump 500 is coupled to the coolant line 596. An outlet of the cold plate 592 may be coupled to a liquid coolant return line 588 of the liquid cooling loop, which returns liquid coolant to the remainder of the loop for eventual cooling (e.g., at a heat exchanger). Thus, when the electronic device 590 is installed in the system 580 and fluidically coupled into the liquid cooling loop 589 thereof, liquid coolant from the loop 589 can flow through the pump 500 and cold plate 592. In particular, the pump 500 may be configured to cause (or at least contribute to) the flowing of the liquid coolant through the cold plate 592 to cool the heat generating component 591. In some examples, two of the pumps 500 are included in the device 590 for redundancy. In some examples (not illustrated), the two pumps are stacked atop one another along the height direction H. In some examples, the electronic device 590 is a 1U-sized device (e.g., sized to fit within one standard rack unit, or 1U), and the two stacked pumps 500 fit within the chassis 594 of the device 590. In some examples, the pump 500 is disposed within a PCI slot of the device 590, which as standard dimensions of a PCE slot.

In the description above, various types of electronic circuitry or devices are described. As used herein, “electronic” is intended to be understood broadly to include all types of circuitry/devices utilizing electricity, including digital and analog circuitry, direct current (DC) and alternating current (AC) circuitry, and circuitry/devices for converting electricity into another form of energy and circuitry/devices for using electricity to perform other functions. In other words, as used herein there is no distinction between “electronic” circuitry/devices and “electrical” circuitry/devices. In some cases, certain electronic circuitry/devices may comprise processing circuitry. Processing circuitry comprises circuitry configured with logic for performing various operations. The logic of the processing circuitry may comprise dedicated hardware to perform various operations, software (machine readable and/or processor executable instructions) to perform various operations, or any combination thereof. In implementations in which the logic comprises software, the processing circuitry may include a processor to execute the software instructions and a memory device that stores the software. The processor may comprise one or more processing devices capable of executing machine readable instructions, such as, for example, a processor, a processor core, a central processing unit (CPU), a controller, a microcontroller, a system-on-chip (SoC), a digital signal processor (DSP), a graphics processing unit (GPU), etc. In cases in which the processing circuitry includes dedicated hardware, in addition to or in lieu of the processor, the dedicated hardware may include any electronic device that is configured to perform specific operations, such as an Application Specific Integrated Circuit (ASIC), a Field Programmable Gate Array (FPGA), a Complex Programmable Logic Device (CPLD), discrete logic circuits, a hardware accelerator, a hardware encoder, etc. The processing circuitry may also include any combination of dedicated hardware and processor plus software.

It is to be understood that both the general description and the detailed description provide example implementations that are explanatory in nature and are intended to provide an understanding of the present disclosure without limiting the scope of the present disclosure. Other examples in accordance with the present disclosure will be apparent to those skilled in the art based on consideration of the disclosure herein. For example, various mechanical, compositional, structural, electronic, and operational changes may be made to the disclosed examples without departing from the scope of this disclosure, including for example the addition, removal, alteration, substitution, or rearrangement of elements of the disclosed examples, as would be apparent to one skilled in the art in consideration of the present disclosure. Moreover, it will be apparent to those skilled in the art that certain features or aspects of the present teachings may be utilized independently (even if they are disclosed together in some examples) or may be utilized together (even if disclosed in separate examples), whenever practical. In some instances, well-known circuits, thermal devices, structures, and techniques have not been shown or described in detail in order not to obscure the examples. Thus, the following claims are intended to be given their fullest breadth, including equivalents, under the applicable law, without being limited to the examples disclosed herein.

References herein to examples, implementations, or other similar references should be understood as referring to prophetic or hypothetical examples, rather than to devices that have been actually produced (e.g., prototypes), unless explicitly indicated otherwise. Similarly, references to qualities or characteristics of examples should be understood as estimates or expectations based on an understanding of the relevant physical principles involved, application of theory or modeling, and/or past experiences of the inventors, rather than as the results of tests carried out on a physical device, unless explicitly indicated otherwise.

Further, spatial, positional, and relational terminology used herein is chosen to aid the reader in understanding examples of the invention but is not intended to limit the invention to a particular reference frame, orientation, or positional relationship. For example, spatial, positional, and relational terms such as “up”, “down”, “lateral”, “beneath”, “below”, “lower”, “above”, “upper”, “proximal”, “distal”, and the like may be used herein to describe directions or to describe one element's or feature's spatial relationship to another element or feature as illustrated in the figures. These spatial terms are used relative to reference frames in the figures and are not limited to a particular reference frame in the real world. Furthermore, if a different reference frame is considered than the one illustrated in the figures, then the spatial terms used herein may need to be interpreted differently in that different reference frame. Moreover, the poses of items illustrated in the figure are chosen for convenience of illustration and description, but in an implementation in practice the items may be posed differently.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition. Moreover, unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

What is claimed is:

1. An axial pump for delivering liquid coolant to cool an electronic device, comprising:
a conduit defining a liquid flow path for the liquid coolant;
an impeller in the conduit;
a motor stator configured to drive rotation of the impeller about an axis of rotation parallel to the liquid flow path; and
a printed circuit board assembly (PCA) comprising a first printed circuit board (PCB) portion and a second PCB portion electrically connected together by a connecting portion, the PCA straddling the conduit such that the first PCB portion is on one lateral side of the conduit and the second PCB portion is on an opposite lateral side of the conduit and the connecting portion extends across the conduit.

2. The axial pump of claim 1,
wherein the first PCB portion and the second PCB portion comprise first and second PCBs, respectively, which are separate and distinct from one another.

3. The axial pump of claim 2,
wherein the connecting portion comprises a first connector coupled to the first PCB and a second connector coupled to the second PCB, the first and second connectors being removably coupled together.

4. The axial pump of claim 3,
wherein the first and second connectors comprise blind mate connectors.

5. The axial pump of claim 3,
wherein at least one of the first and second connectors extends at least partially across the conduit.

6. The axial pump of claim 2,
wherein the connecting portion comprises a protruding portion of the first PCB that protrudes at least partially across the conduit.

7. The axial pump of claim 6,
wherein the connecting portion comprises a first connector coupled to the protruding portion and a second connector coupled to the second PCB, the first and second connectors being removably coupled together.

8. The axial pump of claim 2,
wherein the PCA further comprises a second connecting portion electrically connecting the first PCB to the second PCB, and
wherein the connecting portion extends over the conduit and the second connecting portion extends under the conduit.

9. The axial pump of claim 8,
wherein the connecting portion comprises a first protruding portion of the first PCB that protrudes at least partially across the conduit; and
wherein the second connecting portion comprises a second protruding portion of the first PCB that protrudes at least partially across the conduit.

10. The axial pump of claim 9,
wherein the connecting portion comprises a first connector coupled to the first protruding portion and a second connector coupled to the second PCB, the first and second connectors being removably coupled together, and
wherein the second connecting portion comprises a third connector coupled to the second protruding portion and a fourth connector coupled to the second PCB, the third and fourth connectors being removably coupled together.

11. The axial pump of claim 10,
wherein the connecting portion comprises a fifth connector coupled to the first protruding portion and a sixth connector coupled to the second PCB, the fifth and sixth connectors being removably coupled together, and
wherein the second connecting portion comprises a seventh connector coupled to the second protruding portion and an eighth connector coupled to the second PCB, the seventh and eighth connectors being removably coupled together.

12. The axial pump of claim 1,
wherein the motor stator comprises a first stator portion and a second stator portion respectively arranged on opposite lateral sides of the conduit; and
wherein the first PCB is electrically coupled to the first stator portion and the second PCB is electrically coupled to the second stator portion.

13. The axial pump of claim 1,
wherein the first and second PCB portions of the PCA are disposed between the motor stator and an inlet of the conduit.

14. The axial pump of claim 1,
wherein the first and second PCB portions of the PCA are arranged transverse to the axis of rotation.

15. The axial pump of claim 1,
wherein the axis of rotation passes between the first and second PCBs.

16. The axial pump of claim 1,
wherein the PCA does not contribute to any of the dimensions of the axial pump.

17. An electronic device, comprising:
a printed circuit board (PCB);
an electronic component coupled to the PCB;
a chassis housing the PCB;
a cold plate thermally coupled to the electronic component; and
the axial pump of claim 1 disposed within the chassis, wherein the conduit of the axial pump is fluidically coupled with the cold plate and the PCA is electrically connected to the PCB.

18. A method of manufacturing an axial pump, comprising:
positioning a first stator subassembly on a first lateral side of an impeller subassembly, the first stator subassembly comprising a first stator portion and a first PCB electrically coupled to the first stator portion, the impeller subassembly comprising an impeller chamber and an impeller within the impeller chamber;
positioning a second stator subassembly on a second lateral side of an impeller subassembly, the second stator subassembly comprising a second stator portion and a second PCB electrically coupled to the second stator portion, the first and second PCBs being two separate parts of a split PCA configured to control operation of the axial pump, the first and second stator portions being two separate parts of a motor stator configured to drive rotation of the impeller; and
assembling the first and second stator subassemblies and the impeller subassembly by moving the first and second stator subassemblies towards the impeller subassembly and, by the moving:
capturing the impeller chamber between the first and second stator subassemblies, and
mating together respective electrical connectors of the first and second PCB such that the first and second PCBs are electrically connected together by at least one connecting portion that extends across the conduit, the at least one connecting portion comprising the electrical connectors.

19. The method of claim 18, further comprising:
electrically coupling the first PCB to the first stator portion prior to positioning the first stator subassembly on the first lateral side of the impeller subassembly; and
electrically coupling the second PCB to the second stator portion prior to positioning the second stator subassembly on the second lateral side of the impeller subassembly.

20. The method of claim 18, further comprising:
wherein, in the assembled state of the first and second stator subassemblies and the impeller subassembly, the connecting portion extends across the conduit at a transition zone of the impeller chamber, the transition zone being between an inlet portion of the impeller chamber and a central portion of the impeller chamber.
